(19) United States
(12) Patent Application Publication
(10) Pub. No.: US 2016/0030978 A1
(43) Pub. Date: Feb. 4, 2016

(54) VIBRATION GENERATING DEVICE

(71) Applicant: SAMSUNG ELECTRO-MECHANICS CO., LTD., Suwon-si (KR)

(72) Inventors: Dong Su MOON, Suwon-si (KR); Sang Jin LEE, Suwon-si (KR); Yeon Ho SON, Suwon-si (KR); Kyung Su PARK, Suwon-si (KR); Jae Kyung KIM, Suwon-si (KR); Joon CHOI, Suwon-si (KR)

(73) Assignee: SAMSUNG ELECTRO-MECHANICS CO., LTD., Suwon-si (KR)

(21) Appl. No.: 14/656,986

(22) Filed: Mar. 13, 2015

(30) Foreign Application Priority Data
Jul. 29, 2014 (KR) 10-2014-0096719

(51) Int. Cl. B06B 1/06; H01L 41/053

(52) U.S. Cl. CPC B06B 1/0603; H01L 41/053

(57) ABSTRACT

There is provided a vibration generating device including: a housing having an internal space and including installation bars; a vibration member having through holes which are formed in both end portions thereof and which is fixedly attached to the installation bars by allowing upper end portions of the installation bars to penetrate through the through holes; a piezoelectric element installed on the vibration member; and a fixing unit fixing the vibration member to the installation bars.

### CROSS-REFERENCE TO RELATED APPLICATION

This application claims the priority and benefit of Korean Patent Application No. 10-2014-0096719 filed on Jul. 29, 2014, with the Korean Intellectual Property Office, the disclosure of which is incorporated herein by reference.

### BACKGROUND

The present disclosure relates to a vibration generating device.

The vibration generating device, a device converting electrical energy into mechanical vibrations using the principle of the generation of electromagnetic force, has commonly been mounted in mobile phones, and the like, to be used for silently notifying a user of call reception by transferring vibrations thereto.

In this regard, in recent years, vibration generating devices using piezoelectric elements have been widely used. Such vibration generating devices using piezoelectric elements, utilizing the principle of an inverse piezoelectric effect generating displacement by applying voltage to the piezoelectric element, generates vibratory force by allowing an oscillator to be moved by the generated displacement.

Meanwhile, the oscillator includes a vibration member of which both end portions are fixedly attached to a housing forming an internal space so as to have the piezoelectric element fixedly attached to a central portion thereof. In addition, both end portions of the above-mentioned vibration member are provided to be bonded to the housing by welding.

However, in the case in which external force is applied to the oscillator, when external force is intensively transferred to a bonding portion between the vibration member and the housing, the vibration member may be damaged.

As a result, the development of a structure capable of preventing vibration members from being damaged at the bonding portions thereof formed by the welding is required.

### RELATED ART DOCUMENT

(Patent Document 1) Korean Patent Laid-Open Publication No. 2011-45486

### SUMMARY

An aspect of the present disclosure may provide a vibration generating device capable of preventing a vibration member from being damaged.

According to an aspect of the present disclosure, a vibration generating device may include: a housing having an internal space and including installation bars; a vibration member having through holes which are provided in both end portions thereof and which is fixed to the installation bars by allowing upper end portions of the installation bars to penetrate through the through holes; a piezoelectric element installed on the vibration member; and a fixing unit fixing the vibration member to the installation bars.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a schematic perspective view showing a vibration generating device according to an exemplary embodiment of the present disclosure;

FIG. 2 is an exploded perspective view showing the vibration generating device according to an exemplary embodiment of the present disclosure;

FIG. 3 is an exploded perspective view showing a lower case, a vibration member, and a fixing unit included in the vibration generating device according to an exemplary embodiment of the present disclosure;

FIG. 4 is an exploded perspective view showing a lower case, a vibration member, and a fixing unit included in a vibration generating device according to another exemplary embodiment of the present disclosure;

FIG. 5 is an exploded perspective view showing a first modified example of an installation bar included in the lower case; and

FIG. 6 is an exploded perspective view showing a second modified example of an installation bar included in the lower case.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

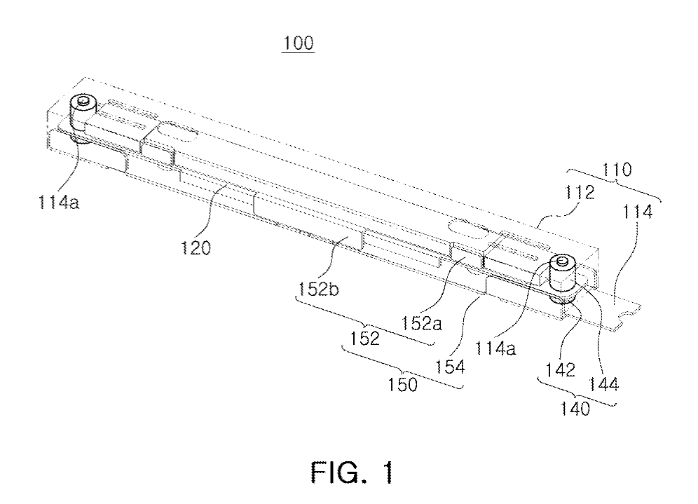

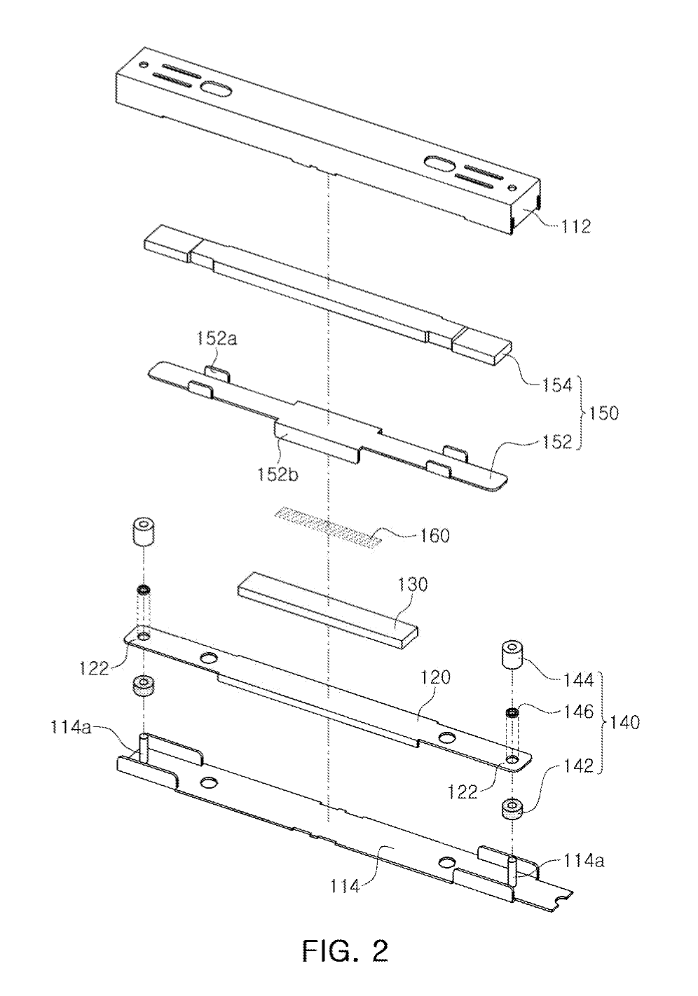

FIG. 1 is a schematic perspective view showing a vibration generating device according to an exemplary embodiment of the present disclosure and FIG. 2 is an exploded perspective view showing the vibration generating device according to an exemplary embodiment of the present disclosure.

Referring to FIGS. 1 and 2, a vibration generating device 100 according to an exemplary embodiment of the present disclosure may include a housing 110, a vibration member 120, a piezoelectric element 130, a fixing unit 140, and a mass body part 150, by way of example.

The housing 110 may have an internal space. Meanwhile, the housing 110 may include an upper case 112 having an internal space and a lower end portion which is opened, and a lower case 114 which is attached to the lower end portion of the upper case 112.

By way of example, the upper case 112 may have a box shape of which a lower end portion is opened, and the lower case 114 may be attached to the lower end portion of the upper case 112, so as to serve to close the lower end portion of the upper case 112.

Meanwhile, the lower case 114 may have installation bars 114a for installing the vibration member 120. The installation bars 114a may be disposed on both end portions of a top surface of the lower case 114 and may have a cylindrical shape having a circular cross section, by way of example.

However, although the present exemplary embodiment describes a case in which the installation bars 114a are provided to the lower case 114, by way of example, the present disclosure is not limited thereto. For example, the installation bars 114a may also be provided to the upper case 112.

The vibration member 120 may have a plate shape and both end portions of the vibration member 120 may be provided with through holes 122 through which upper end portions of the installation bars 114a may penetrate. That is, the vibration member 120 may be fixedly installed in the installation bars 114a.

Meanwhile, in the case in which the piezoelectric element 130 is applied with power, the vibration member 120 may be linked with the piezoelectric element 130 to be vibrated. That is, both end portions of the vibration member 120 may be fixed by the installation bars 114a and a central portion therefore may be vertically vibrated.

In addition, although the present exemplary embodiment describes a case in which the vibration member 120 has a quadrangular plate shape by way of example, the shape of the vibration member 120 is not limited thereto.

The piezoelectric element 130 may be installed on one surface of the vibration member 120. As an example, the piezoelectric element 130 may be installed on a top surface of the vibration member 120. Meanwhile, in the case in which power is supplied to the piezoelectric element 130, the piezoelectric element 130 may be vertically bent so as to serve to vibrate the vibration member 120. To this end, the piezoelectric element 130 may have at least one pair of external electrodes (not illustrated), wherein the external electrodes may include a positive (+) electrode and a negative (−) electrode.

Meanwhile, a circuit board (not shown) may be connected to the piezoelectric element 130, wherein one side of the circuit board may be connected to the external electrodes of the piezoelectric element 130 and the other side thereof may be led external to the housing 110, to be connected to an external power supply.

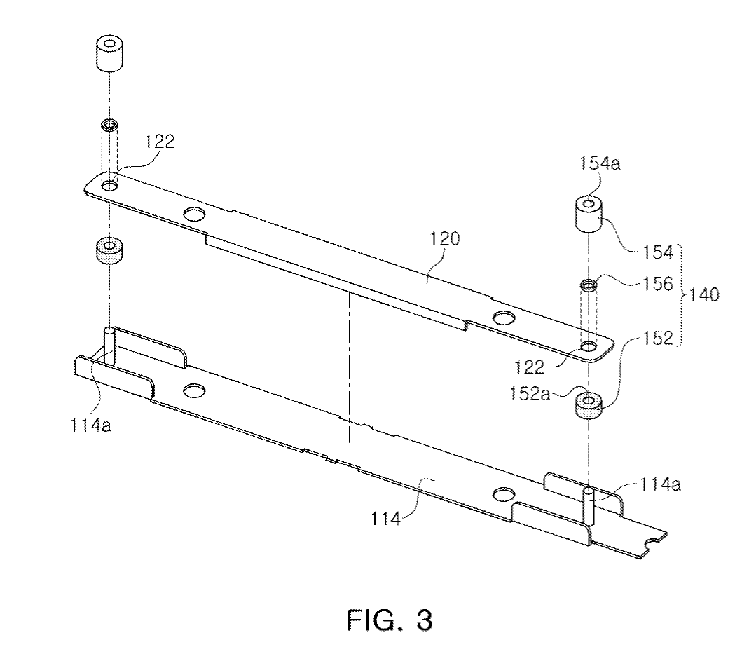

The fixing unit 140 will be described with reference to FIG. 3.

The fixing unit 140 may serve to fix the vibration member 120 to the installation bars 114a. To this end, the fixing unit 140 may include a lower supporting member 142, an upper supporting member 144, and a bush 146.

As shown in FIG. 3, the lower supporting member 142 may support a bottom surface of the vibration member 120. In addition, the lower supporting member 142 may have an installation hole 142a formed therein so that the lower supporting member 142 may be installed in the installation bar 114a. That is, the lower supporting member 142 may be installed in the installation bar 114a to be disposed below the vibration member 120, and may support the bottom surface of the vibration member 120 in the case in which the vibration member 120 is installed.

Consequently, the vibration member 120 may be disposed to be spaced apart from the top surface of the lower case 114 of the housing 110 by a predetermined interval.

Meanwhile, the lower supporting member 142 may have a hollow ring shape.

The upper supporting member 144 may support the top surface of the vibration member 120. In addition, the upper supporting member 144 may also have an installation hole 144a formed therein for installation in the installation bar 114a. That is, the upper supporting member 144 may be installed in the installation bar 114a to be disposed over the vibration member 120, and may support the top surface of the vibration member 120 in the case in which the vibration member 120 is installed.

As such, the vibration member 120 may be installed in the installation bar 114a to be disposed between the upper supporting member 144 and the lower supporting member 142, and may be fixedly installed in the installation bar 114a by the lower supporting member 142 and the upper supporting member 144.

Meanwhile, the upper supporting member 144 may have a hollow ring shape, similar to the lower supporting member 142, and may have a thickness thicker than that of the lower supporting member 142.

However, although the present exemplary embodiment describes a case in which the upper supporting member 144 has the thickness thicker than that of the lower supporting member 142 by way of example, the present disclosure is not limited thereto. For example, the lower supporting member 142 may also have the thickness thicker than that of the upper supporting member 144.

The bush 146 may be attached to the installation bar 114a to be disposed in the through hole 122 of the vibration member 120. That is, in order to reduce interference between the installation bar 114a and the vibration member 120 at the time of the vibration of the vibration member 120, the bush 146 formed of a material having elasticity may be installed in the installation bar 114a.

In addition, since the bush 146 is formed of the material having elasticity, stress concentration by the installation bar 114a at the time of the vibration of the vibration member 120 may be reduced.

However, the material of the bush 146 is not limited to the material having elasticity. For example, the bush 146 may be formed of various materials capable of preventing stress from being directly transferred to the vibration member 120. That is, the bush 146 may also be formed of, for example, a synthetic resin material or a stainless material.

As such, since the vibration member 120 may be fixedly installed in the installation bars 114a by the lower supporting member 142 and the upper supporting member 144, it may be avoided to install the vibration member 120 onto the lower case 114 by welding.

Consequently, a stress concentration phenomenon of portions in which thermal deformation occurs by the welding may be prevented, and as a result, damage to the vibration member 120 that occurs at the time of the installation of the vibration member 120 by the welding may be prevented.

Further, since the vibration member 120 is fixedly installed by the lower supporting member 142 and the upper supporting member 144, an assembly may be easily performed. Therefore, a manufacturing yield may be improved.

Further, by adjusting the thicknesses of the lower supporting member 142 and the upper supporting member 144, a distance that the vibration member 120 is spaced apart from the housing 110 may be easily adjusted.

Meanwhile, the mass body part 150 will be described with reference to FIGS. 1 and 2.

Meanwhile, the mass body part 150 may be connected to a top surface of the piezoelectric element 130 by a bonding member 160. Meanwhile, the mass body part 150 may be linked with the vibration member 120 to be vibrated, thereby serving to amplify the vibration of the vibration member 120.

In addition, the mass body part 150 may include a mass body case 152 and a mass body 154.

The mass body case 152 may have a bottom surface bonded to the bonding member 160 and a top surface on which the mass body 154 is fixedly installed.

In addition, the mass body case 152 may be provided with a supporting plate 152a for supporting both sides of the mass body 154, wherein the supporting plate 152a may be formed in plural.

Meanwhile, the mass body case 152 may have a protrusion portion 152b formed at the central portion thereof, wherein the protrusion portion 152b may be formed to be extended to a lower side of the mass body case 152. In the case in which the vibration member 120 is abnormally vibrated due to an external impact, the protrusion portion 152b may serve to allow the mass body case 152 to be in contact with the lower case 114 before the vibration member 120 is in contact with the lower case 114.

Therefore, external force applied to the piezoelectric element 130 may be decreased, which results in a reduction in damage to the piezoelectric element 130.

The mass body 154 may be installed on the mass body case 152 and may be formed of a material having a large specific gravity. As an example, the mass body 154 may have a rectangular parallelepiped shape and may be fixedly installed onto the mass body case 152 so that both sides thereof are supported by the supporting plates 152a in a state in which the mass body 154 is seated on the top surface of the mass body case 152.

In addition, the top surface of the mass body 154 may be installed with a damper member (not shown) for preventing noise occurrence and damage caused by the contact with the upper case 112 at the time of the vibration.

As described above, since the vibration member 120 may be installed in the installation bars 114a of the lower case 114 by the fixing unit 140, the damage to the vibration member 120 may be prevented.

That is, the vibration member 120 is installed on the lower case 114 without using the welding, and as a result, the stress concentration phenomenon does not occur in the portions in which the thermal deformation occurs by the welding, whereby the damage to the vibration member 120 may be prevented.

In addition, since the vibration member 120 may be installed on the lower case 114 by the lower supporting member 142 and the upper supporting member 144, an assembly may be easily performed.

Hereinafter, a vibration generating device according to another exemplary embodiment of the present disclosure will be described with reference to the accompanying drawings. However, an illustration in the drawings and a detailed description of the same components as the above-mentioned components will be omitted and be replaced by the above-mentioned description.

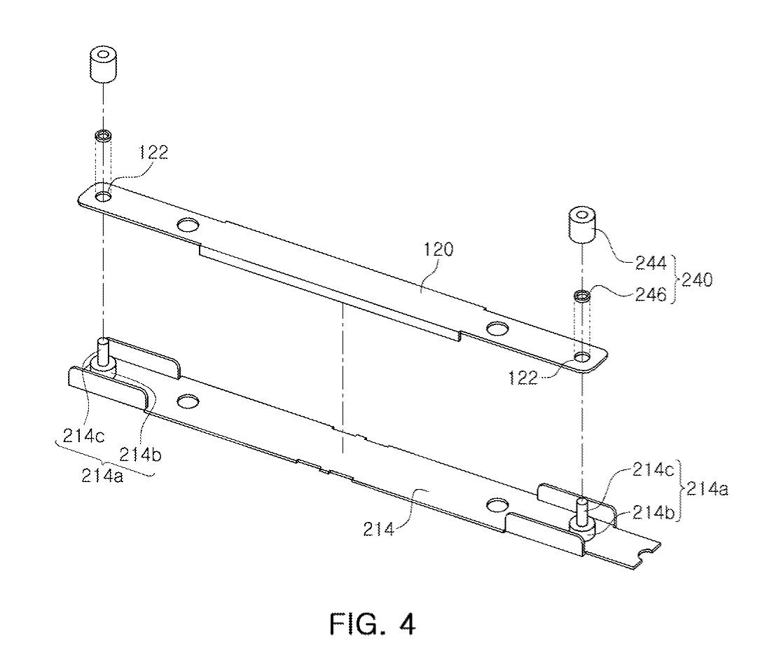

FIG. 4 is an exploded perspective view showing a lower case, a vibration member, and a fixing unit included in a vibration generating device according to another exemplary embodiment of the present disclosure.

Referring to FIG. 4, a lower case 214 may have installation bars 214a for installing the vibration member 120. The installation bars 214a may be disposed at both end portions of a top surface of the lower case 214.

Meanwhile, the installation bar 214a may include a supporting portion 214b supporting a bottom surface of the vibration member 120, and an installation portion 214c formed to be extended from the supporting portion 214b and penetrating through the through hole 122.

That is, the vibration member 120 may be installed to be seated on a top surface of the supporting portion 214b, wherein the supporting portion 214b may be formed so as to have a diameter larger than that of the installation portion 214c.

The vibration member 120 may have a plate shape and both end portions thereof may be provided with the through holes 122 through which the installation portions 214c of the installation bars 214a described above penetrate. That is, the vibration member 120 may be fixedly installed in the installation bars 214a.

Meanwhile, since the vibration member 120 is the same component as that described above, a detailed description thereof will be omitted.

The fixing unit 240 may serve to fix the vibration member 120 to the installation bars 214a. To this end, the fixing unit 240 may include an upper supporting member 244 and a bush 246.

The upper supporting member 244 may support the top surface of the vibration member 120. In addition, the upper supporting member 244 may have an installation hole 214a formed therein for installation in the installation bar 214a. That is, the upper supporting member 244 may be installed in the installation bar 214a to be disposed over the vibration member 120, and may support the top surface of the vibration member 120 in the case in which the vibration member 120 is installed.

As such, the vibration member 120 may be installed in the installation bar 214a to be disposed between the supporting portion 214b of the installation bar 214a and the upper supporting member 244, and may be fixedly installed in the installation bar 214a by the upper supporting member 244.

Meanwhile, the upper supporting member 244 may have a hollow ring shape.

The bush 246 may be attached to the installation bar 214a to be disposed in the through hole 122 of the vibration member 120. That is, in order to reduce interference between the installation bar 214a and the vibration member 120 at the time of the vibration of the vibration member 120, the bush 246 formed of a material having elasticity may be installed in the installation bar 214a.

In addition, since the bush 246 is formed of the material having elasticity, stress concentration by the installation bar 214a at the time of the vibration of the vibration member 120 may be reduced.

As such, since the vibration member 120 may be fixedly installed in the installation bar 214a by the upper supporting member 244, it may be avoided to install the vibration member 120 onto the lower case 214 by welding.

Consequently, a stress concentration phenomenon of portions in which thermal deformation occurs by the welding may be prevented, and as a result, damage to the vibration member 120 that occurs at the time of the installation of the vibration member 120 may be prevented by the welding.

Further, since the vibration member 120 is fixedly installed in the installation bar 214a by the upper supporting member 244, an assembly may be easily performed. Therefore, a manufacturing yield may be improved.

Hereinafter, a modified example of the installation bar included in the lower case will be described with reference to the accompanying drawings.

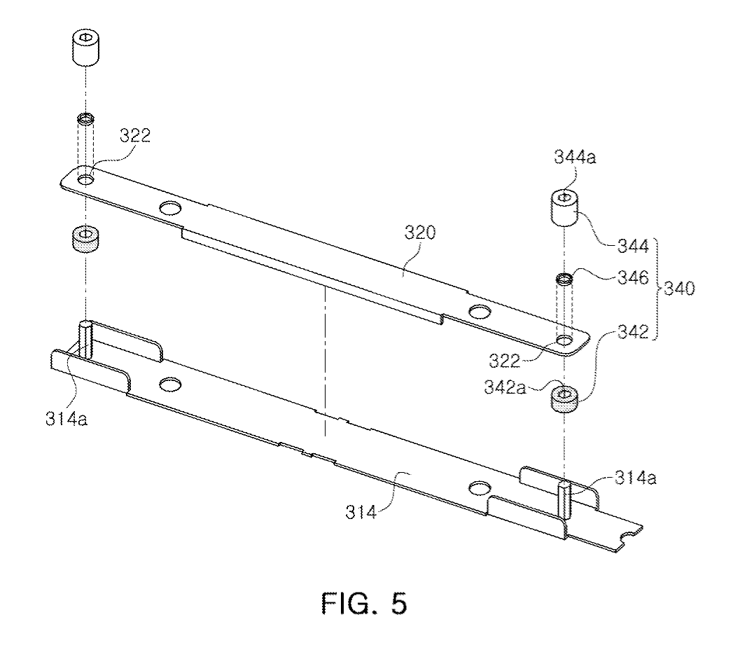

FIG. 5 is an exploded perspective view showing a first modified example of an installation bar included in the lower case.

Referring to FIG. 5, a lower case 314 may have installation bar 314a for installing a vibration member 320. The installation bars 314a may be disposed at both end portions of a top surface of the lower case 314.

Meanwhile, the installation bar 314a may have a hexagonal cylinder shape having a cross section of a hexagonal shape.

In addition, a through hole 322 of the vibration member 320 may also have the hexagonal shape so as to correspond to the shape of the installation bar 314a.

In addition, installation holes 342a and 344a of a lower supporting member 342 and an upper supporting member 344 of a fixing unit 340 may also have the hexagonal shape.

As such, warpage occurring at the time of the installation of the vibration member 320 may be reduced by the installation bars 314a having the hexagonal shape.

As described above, since the vibration member 320 may be installed in the installation bars 314a of the lower case 314 by the fixing unit 340, damage to the vibration member 320 may be prevented.

That is, the vibration member 320 is installed on the lower case 314 without using the welding, and as a result, the stress concentration phenomenon does not occur in the portions in which the thermal deformation occurs by the welding, whereby the damage to the vibration member 320 may be prevented.

In addition, since the vibration member 320 may be installed on the lower case 314 by the lower supporting member 342 and the upper supporting member 344, an assembly may be easily performed.

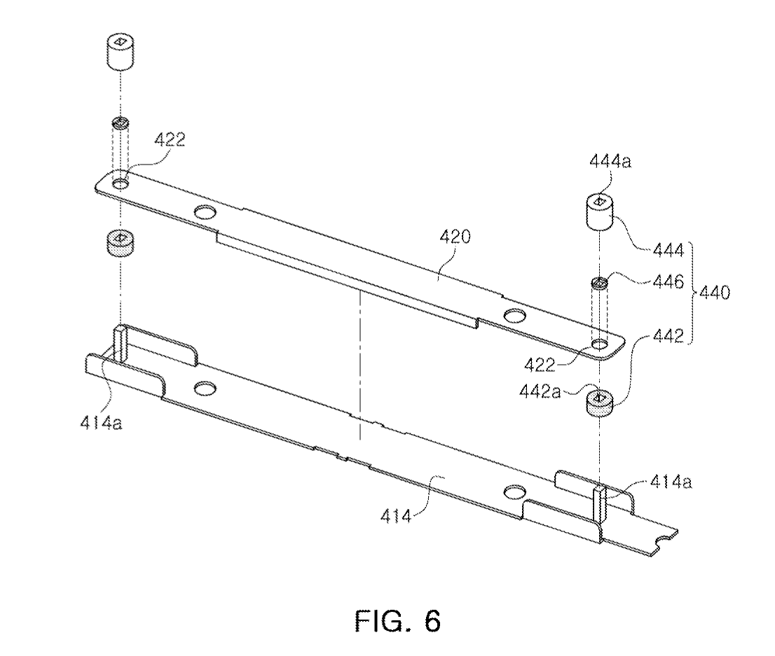

FIG. 6 is an exploded perspective view showing a second modified example of an installation bar included in the lower case.

Referring to FIG. 6, a lower case 414 may have an installation bar 414a for installing a vibration member 420. The installation bars 414a may be disposed at both end portions of a top surface of the lower case 414.

Meanwhile, the installation bar 414a may have a quadrangular cylinder shape having a cross section of a quadrangular shape.

In addition, a through hole 422 of the vibration member 420 may also have the quadrangular shape so as to correspond to the shape of the installation bar 414a.

In addition, installation holes 442a and 444a of a lower supporting member 442 and an upper supporting member 444 of a fixing unit 440 may also have the quadrangular shape.

As such, warpage occurring at the time of the installation of the vibration member 420 may be reduced by the installation bars 414a having the quadrangular shape.

As described above, since the vibration member 420 may be installed in the installation bars 414a of the lower case 414 by the fixing unit 440, damage to the vibration member 420 may be prevented.

That is, the vibration member 420 is installed on the lower case 414 without using the welding, and as a result, the stress concentration phenomenon does not occur in the portions in which the thermal deformation occurs by the welding, whereby the damage to the vibration member 420 may be prevented.

In addition, since the vibration member 420 may be installed on the lower case 414 by the lower supporting member 442 and the upper supporting member 444, an assembly may be easily performed.

As set forth above, according to exemplary embodiments of the present disclosure, the damage to the vibration member may be prevented.

While exemplary embodiments have been shown and described above, it will be apparent to those skilled in the art that modifications and variations could be made without departing from the scope of the present invention as defined by the appended claims.

What is claimed is:

1. A vibration generating device comprising:
a housing having an internal space and including installation bars;
a vibration member having through holes which are provided in both end portions thereof and which is fixed to the installation bars by allowing upper end portions of the installation bars to penetrate through the through holes;
a piezoelectric element installed on the vibration member; and
a fixing unit fixing the vibration member to the installation bars.

2. The vibration generating device of claim 1, wherein the fixing unit includes lower supporting members supporting a bottom surface of the vibration member and upper supporting members supporting a top surface of the vibration member.

3. The vibration generating device of claim 2, wherein the lower supporting member is thinner than the upper supporting member.

4. The vibration generating device of claim 2, wherein the fixing unit further includes bushes attached to the installation bars to be disposed in the through holes.

5. The vibration generating device of claim 1, further comprising a mass body part connected to a top surface of the piezoelectric element by a bonding member.

6. The vibration generating device of claim 5, wherein the mass body part includes a mass body case bonded to the bonding member and a mass body installed on the mass body case.

7. The vibration generating device of claim 1, wherein the housing includes an upper case having an internal space and a lower case attached to a lower end portion of the upper case, and
the installation bars protrude from both end portions of the lower case.

8. The vibration generating device of claim 6, wherein the mass body case has a protrusion portion which is extended downwardly from a central portion of the mass body case.

9. The vibration generating device of claim 7, wherein the installation bars are molded integrally with the lower case and have a circular or polygonal cross section.

10. The vibration generating device of claim 1, wherein the installation bars include supporting portions supporting a bottom surface of the vibration member and installation portions extended from the supporting portions and penetrating through the through holes.

11. The vibration generating device of claim 10, wherein the fixing unit includes upper supporting members attached to upper portions of the installation portions and bushes disposed in the through holes.

12. A vibration generating device comprising:
an upper case in which an internal space is provided and of which a lower side is open;
a lower case attached to a lower end portion of the upper case and having installation bars which are provided on both end portions thereof;
a vibration member having through holes through which upper end portions of the installation bars penetrate;
a piezoelectric element installed on the vibration member;
a mass body part installed on a top surface of the piezoelectric element by a bonding member;
lower supporting members installed in the installation bars to support a bottom surface of the vibration member;
upper supporting members installed in the installation bars to support a top surface of the vibration member; and
bushes installed in the installation bars to be disposed in the through holes.
